(19) United States
(12) Patent Application Publication
(10) Pub. No.: US 2020/0028061 A1
(43) Pub. Date: Jan. 23, 2020

(54) CONNECTION STRUCTURE

(71) Applicant: FURUKAWA ELECTRIC CO., LTD., Tokyo (JP)

(72) Inventors: Akinobu NAKAI, Tokyo (JP); Satoshi YAMANO, Tokyo (JP); Hisaki SAKAMOTO, Tokyo (JP)

(73) Assignee: FURUKAWA ELECTRIC CO., LTD., Tokyo (JP)

(21) Appl. No.: 16/586,313

(22) Filed: Sep. 27, 2019

Related U.S. Application Data
(63) Continuation of application No. PCT/JP2018/012947, filed on Mar. 28, 2018.

(30) Foreign Application Priority Data
Mar. 30, 2017 (JP) 2017-066709

(51) Int. Cl. H01L 39/02; H01R 43/00; H01R 4/68

(52) U.S. Cl. CPC H01L 39/02; H01R 4/68; H01R 43/00

(57) ABSTRACT

A connection structure of the present disclosure includes first and second superconducting wires that are two superconducting wires each having a substrate in a tape shape, an intermediate layer formed on the substrate, and a superconductor layer formed on the intermediate layer, a connecting superconductor layer that connects the first and second superconducting wires in a positional relationship in which surfaces of the superconductor layers face each other, and forms a superconducting connecting section together with the first and second superconducting wires, two protective members each having a width larger than a width of the first and second superconducting wires and disposed on substrates sides of the first and second superconducting wires in a positional relationship of sandwiching the superconducting connecting section, and a metal part that joins the two protective members to each other.

### CROSS REFERENCE TO RELATED APPLICATIONS

The present application is a continuation application of International Patent Application No. PCT/JP2018/012947 filed on Mar. 28, 2018, which claims the benefit of Japanese Patent Application No. 2017-066709, filed on Mar. 30, 2017. The contents of these applications are incorporated herein by reference in their entirety.

### BACKGROUND

### Technical Field

The present disclosure relates to a connection structure, and in particular, to a connection structure of superconducting wires.

### Background

Recently, as oxide superconductors having critical temperature (Tc) that is higher than liquid nitrogen temperature (about 77 K), high temperature superconductors such as YBCO system (Yttrium-based) and BSCCO system (bismuth-based), for example, have attracted attention. As superconducting wires manufactured with use of such high temperature superconductors, superconducting wires having a superconductor layer, formed by depositing an oxide superconductor film on a metal substrate of a metal or the like that is long and flexible, or depositing an oxide superconductor film on a single crystal substrate, are known.

Superconducting wires are considered to be applied as coil windings for magnetic resonance imaging (MRI), nuclear magnetic resonance (NMR), and the like, for example, and a demand for long superconducting wires is increasing. However, the length of a single continuous superconducting wire has a limitation in manufacturing. In order to obtain a coil winding of a desired length, it is necessary to connect superconducting wires with each other.

As a connection structure in which superconducting wires are connected with each other, Japanese Patent Application Laid-Open No. 2011-165435 discloses a connection structure of superconducting wires in which end portions of two superconducting wires in which both surfaces are covered with a reinforcing material are overlapped and connected by soldering. However, in the connection structure of Japanese Patent Application Laid-Open No. 2011-165435, solder is used for connecting superconducting wires. Therefore, it is difficult to make electrical resistance in the connecting section of the superconducting wires zero due to intervention of the solder.

As another method of connecting superconducting wires with each other, Japanese Patent Application Laid-Open No. 2013-235699 discloses a method of arranging a superconductor layer exposed at a connecting end portion of one superconducting wire and a superconductor layer exposed at a connecting end portion of the other superconducting wire in an opposed state, and between them, forming a superconducting joint layer formed by the metal organic deposition (MOD) method.

However, in the connection structure disclosed in Japanese Patent Application Laid-Open No. 2013-235699, a superconducting joint layer formed by the MOD method, interposed between the superconductor layer of one superconducting wire and the superconductor layer of the other superconducting wire, connects the superconducting wires with each other, and the strength of the superconductor joint layer itself is low. Therefore, when an undesired force is applied to the superconducting wires, the superconducting wires may be separated from the superconducting joint layer.

### SUMMARY

The present disclosure is related to providing a connection structure of superconducting wires having high connection strength.

In accordance with one aspect of the present disclosure, a connection structure includes first and second superconducting wires that are two superconducting wires each having a substrate in a tape shape, an intermediate layer formed on the substrate, and a superconductor layer formed on the intermediate layer; a connecting superconductor layer that connects the first and second superconducting wires in a positional relationship in which surfaces of the superconductor layers face each other, and forms a superconducting connecting section together with the first and second superconducting wires; two protective members each having a width larger than a width of the first and second superconducting wires, and disposed on substrate sides of the first and second superconducting wires in a positional relationship of sandwiching the superconducting connecting section; and an a metal part that joins the two protective members to each other.

It is preferable that in the connecting structure, each of the first and second conducting wires further includes a metal protective layer that covers an entire surface of the superconductor layer except for the superconducting connection section.

In the connection structure, it is preferable that the metal parts are provided in at least four positions surrounding the superconducting connecting section.

In the connection structure, it is preferable that the metal part is metal or alloy including at least one of Ag, Au, and Cu.

In the connection structure, it is preferable that a difference between an elastic coefficient of the substrate and an elastic coefficient of the protective member is in a range of 80 GPa or less.

In the connection structure, it is preferable that the elastic coefficient of the protective member ranges from 150 GPa to 250 GPa.

In the connection structure, it is preferable that a melting point of the protective member is equal to or higher than 1000° C.

In the connection structure, it is preferable that a thickness of the protective member ranges from 30 μm to 300 μm.

It is also preferable that the protective member is Ni-based alloy, stainless steel, or carbon steel.

According to the present disclosure, it is possible to provide a connection structure of superconducting wires having high connection strength, and to improve the manufacturing yield of connection structures.

### BRIEF DESCRIPTION OF THE DRAWINGS

FIG. 1 is a schematic cross-sectional view of a superconducting wire constituting a connection structure according to the present disclosure.

FIG. 2 is a schematic cross-sectional view of a connection structure of a first embodiment according to the present disclosure.

FIG. 3 is a top view of the connection structure illustrated in FIG. 2.

FIGS. 4A to 4D are diagrams for explaining a method of manufacturing a connection structure.

FIG. 5 is a schematic cross-sectional view of a connection structure of a second embodiment according to the present disclosure.

FIG. 6 is a schematic cross-sectional view of a connection structure of a third embodiment according to the present disclosure.

FIG. 7 is a perspective view of a connection structure of a fourth embodiment according to the present disclosure.

FIG. 8A is a top view of a connection structure of a fifth embodiment according to the present disclosure, and FIG. 8B is a perspective view illustrating, by extracting, a metal part constituting the connection structure of FIG. 8A.

FIG. 9 is a schematic perspective view of a connection structure of a sixth embodiment of the present disclosure.

FIG. 10 is a schematic perspective view of a connection structure of a seventh embodiment according to the present disclosure.

### DETAILED DESCRIPTION

Hereinafter, a connection structure of the present disclosure will be described with reference to the accompanying drawings. In the following description, a numerical range represented by using “to” means a range including numerical values described before and after “to” as lower and upper limits.

### First Embodiment

### <Superconducting Wire>

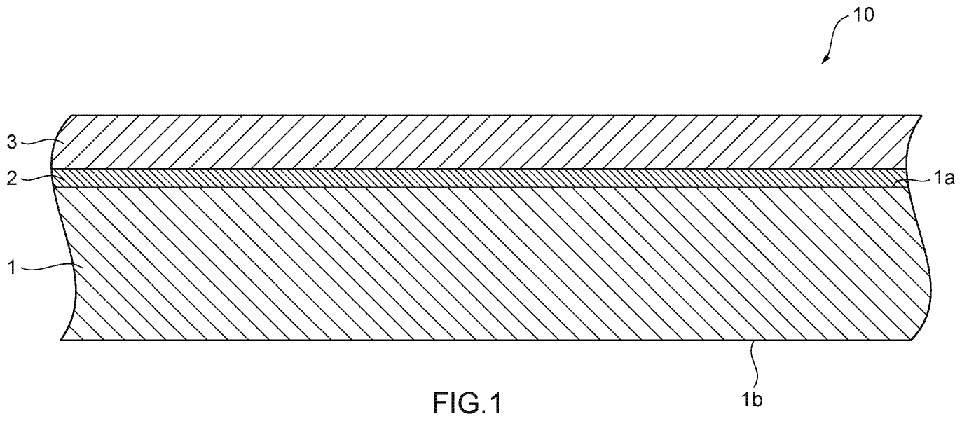

FIG. 1 is a schematic cross-sectional view of a superconducting wire constituting a connection structure according to the present disclosure. A superconducting wire 10 illustrated in FIG. 1 is formed such that on one surface 1a in the thickness direction of a substrate 1 for superconducting film formation, an intermediate layer 2 and a superconductor layer 3 are formed in this order. The superconducting wire 10 is configured as a layered structure of the substrate 1, the intermediate layer 2, and the superconductor layer 3.

The substrate 1 is configured of a metal substrate or a ceramic substrate having a low magnetism in a tape form. As a material of the metal substrate, a metal such as Co, Cu, Cr, Ni, Ti, Mo, Nb, Ta, W, Mn, Fe, Ag, or the like or an alloy of these metals that is excellent in strength and heat resistance may be used, for example. In particular, from a viewpoint of excellent corrosion resistance and heat resistance, it is preferable to use a Ni-based alloy such as Hastelloy (registered trademark) or Inconel (registered trademark), or a Fe-based alloy such as stainless steel. It is more preferable to use Hastelloy (registered trademark) that is a Ni—Fe—Mo-based alloy. The thickness of the substrate 1 is preferably 30 to 100 μm, and more preferably, 30 to 50 μm, although not limited particularly.

The intermediate layer 2 is formed on the substrate 1, and is a base layer formed so that the superconductor layer 3 realizes high biaxial orientation, for example. Such an intermediate layer 2 is made of a material in which physical property values such as a thermal expansion and a lattice constant show intermediate values of those of the substrate 1 and a superconductor constituting the superconductor layer 3. The intermediate layer 2 may have a single-layer structure or a multilayer structure. In the case where the intermediate layer 2 is formed to have a multilayer structure, it can be configured by sequentially laminating a bed layer containing non-crystalline Gd₂Zr₂O_{7-δ} (δ represents the oxygen non-stoichiometric amount), Al₂O₃, Y₂O₃, or the like, a forced alignment layer containing crystalline MgO or the like and formed by the ion beam assisted deposition (IBAD) method, and an LMO layer containing LaMnO_{3+δ} (δ represents the oxygen non-stoichiometric amount), for example, although the number of layers and the type are not limited. Moreover, a cap layer containing CeO₂ or the like may be further provided on the LMO layer. While the thickness of each layer is not particularly limited, examples include that the Y₂O₃ layer of the bed layer is 7 nm, the Al₂O₃ layers is 80 nm, the MgO layer of the forced alignment layer is 40 nm, and the LMO layer is 30 nm.

The Superconductor layer 3 is formed on the intermediate layer 2. It is preferable that the superconductor layer 3 is formed of a high-temperature superconductor in which the transition temperature of the superconductor is higher than the boiling point (−196° C.: 77K) of liquid nitrogen. In particular, it is more preferable that the superconductor layer 3 contains a copper oxide superconductor. As a copper oxide superconductor, a high temperature superconductor such as REBa₂Cu₃O_{7-δ} (RE-based superconductor) is preferred, for example. Note that RE in a RE-based superconductor is a single rare earth element or a plurality of rare earth elements such as Y, Nd, Sm, Eu, Gd, Dy, Ho, Er, Tm, Yb, and Lu. Also, δ is an oxygen non-stoichiometric amount, and is equal to or greater than 0 and equal to or less than 1, for example. From the viewpoint that the superconducting transition temperature is high, it is preferable that δ is closer to 0. Note that when high-pressure oxygen annealing or the like is performed with use of a device such as an autoclave, the oxygen non-stoichiometric amount, represented by δ, may take a value less than 0, that is, a negative value. The thickness of the superconductor layer 3 is preferably 0.1 to 10 μm, and more preferably, 0.5 to 5 μm.

Furthermore, it is preferable that the superconducting wire 10 further includes a metal protective layer 4 that covers the entire surface of the superconductor layer 3 except for a superconducting connecting section C to be described below. In addition, the superconducting wire 10 may further include the metal protective layer 4 also on a surface 1b of the substrate 1, on the opposite side of the surface 1a on which the intermediate layer 2 is formed. The metal protective layer 4 is preferably a metal layer or an alloy layer including at least one of Ag, Au, and Cu, and more preferably, a metal layer of Ag. The material of the metal protective layer 4 may be the same as or different from the material of a metal part 9 to be described below. The thickness of the metal protective layer 4 is preferably 30 to 300 μm, and more preferably, 30 to 100 μm. When the metal protective layer 4 is formed on the surface of the superconductor layer 3, protection can be made effectively without exposing the surface of the superconductor layer 3. Further, when the metal protective layer 4 is provided on the surface 1b side of the substrate 1, in the connection structure 20 to be described below, the protective member 7 and the superconducting wire 10 can be joined via the metal protective layer 4 provided on the surface 1b side of the substrate 1. Thereby, it is possible to further strengthen the reinforcing effect of the superconducting connecting section C. Note that with respect to the lengthwise dimension of the metal protective layer 4, it is not particularly limited. The metal protective layer 4 may be formed to be longer or may be formed to be shorter than the protective member 7, or may be formed to have the same length as that of the protective member 7.

### <Connection Structure>

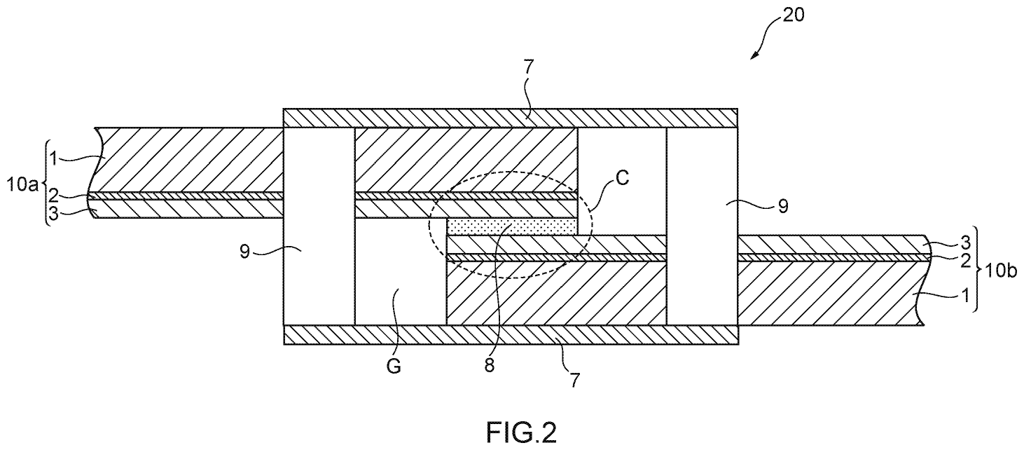

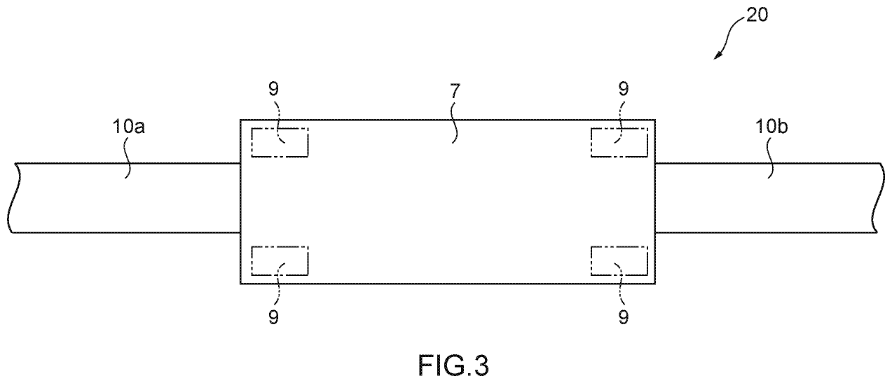

FIG. 2 is a schematic cross-sectional view of a connection structure of a first embodiment according to the present disclosure, and FIG. 3 is a top view of the connection structure illustrated in FIG. 2. The connection structure 20 illustrated in the figures includes two superconducting wires namely a first superconducting wire 10a (hereinafter, simply referred to as “superconducting wire 10a”) and a second superconducting wire 10b (hereinafter, simply referred to as “superconducting wire 10b”), a connecting superconductor layer 8, and two protective members 7 and 7, and a metal part 9.

In FIG. 2, the superconducting wires 10a and 10b are connected such that end portions of the superconducting wires 10a and 10b are connected in a positional relationship that surfaces of the superconductor layers 3 and 3 face each other via the connecting superconductor layer 8, and the connecting superconductor layer 8 forms the superconducting connecting section C (portion surrounded by broken lines in FIG. 2) together with the superconducting wires 10a and 10b. Also, two protective members 7 and 7 having a larger width than that of the superconducting wires 10a and 10b are arranged on the substrates 1 and 1 sides of the superconducting wires 10a and 10b, in a positional relationship of sandwiching the superconducting connecting section C. Moreover, the two protective members 7 and 7 are joined to each other at positions on both sides crossing the superconducting wires 10a and 10b in the width direction, by the metal parts 9 that are preferably formed in at least four locations (in FIG. 3, locations of four corners of the protective members 7) surrounding the superconducting connecting section C.

Such a connection structure 20 has a sandwich structure in which the superconducting wires 10a and 10b are interposed between the two protective members 7 and 7, and the protective members 7 and 7 are joined to each other by the metal parts 9. Therefore, as a result that the superconducting connecting section C is reinforced with two protective members 7 and 7, the connection state of the superconducting wires 10a and 10b can be firmly held.

Note that the two protective members 7 and 7 are fixed by the metal parts 9 in a state where a mutually attractive force of a level not changing the thickness is acted in a direction of sandwiching the superconducting wires 10a and 10b. Therefore, in the connection structure 20, the superconducting wires 10a and 10b are connected with each other with high connection strength. As a result, in the superconducting connecting section C, occurrence of separation between the superconducting wires 10a and 10b can be suppressed effectively, and the manufacturing yield of the connection structures 20 can be improved. Further, since the superconducting connecting section C is covered with the two protective members 7 and 7, it is possible to effectively protect the superconducting connecting section C, and even if an external load such as an undesirable external force is applied to the connection structure 20, it is possible to effectively suppress braking of the superconducting connecting section C. Furthermore, since the metal parts 9 are provided at locations away from the superconducting connecting section C, it is possible to reduce a risk that the connecting superconductor layer 8 is burned due to an influence of joining (fusion) of the metal parts 9.

Furthermore, since a gap G is formed between the two protective members 7 and 7, at the time of manufacturing the connection structure 20, it is possible to secure a supply channel for oxygen, and consequently, crystallization of the connecting superconductor layer 8 can be promoted.

### (Connecting Superconductor Layer)

It is preferable that the connecting superconductor layer 8 is configured of composition of a superconductor that is the same as that of the superconductor layer 3. In particular, the connecting superconductor layer 8 can be formed with use of a composition (solution) containing a raw material necessary for forming an RE-based superconductor. As such a solution, it is possible to use an acetylacetonate or naphthenate MOD solution or the like containing RE (rare earth elements such as yttrium (Y), gadolinium (Gd), samarium (Sm), and holmium (Ho)), Ba, and Cu in a ratio of about 1:2:3, for example. The connecting superconductor layer 8 having crystallinity can be obtained by applying a MOD solution onto the superconducting wires 10a and 10b and performing firing under predetermined conditions.

### (Protective Member)

Next, the protective member 7 will be described in detail. It is preferable that the protective member 7 has a material that can be pressurized and fired together with the superconducting wires 10a and 10b forming the superconductive connecting section C, and that the material is capable of withstanding the firing temperature of approximately 800° C. Accordingly, the melting point of the protective member 7 is preferably 1000° C. or higher, and more preferably, 1200° C. or higher. It is also preferable that a mutually attracting force to the extent that a force is applied to the superconducting connecting section C is applied between the two protective members 7 and 7. Therefore, it is preferable that the protective member 7 is configured of the same material as that of the substrate 1 of the superconducting wires 10a and 10b having such strength and heat resistance. However, the protective member 7 may be configured of a material different from that of the substrate 1. Such a protective member 7 includes a metal material such as Ni-based alloy, stainless steel, or carbon steel, for example.

Furthermore, in the protective member 7, it is preferable that a difference between the elastic coefficient of the substrate 1 and the elastic coefficient of the protective member 7 is within a range of 80 GPa or less, from the viewpoint of strength balance between the components constituting the connection structure 20. When the difference between the elastic coefficients is greater than 80 GPa, stress is not uniformly applied to the connecting section, so that good connection cannot be made.

The elastic coefficient of the protective member 7 may be determined in consideration of the difference between it and the elastic coefficient of the substrate, and it is not particularly limited. For example, the elastic coefficient is preferably 150 GPa to 250 GPa, and more preferably, 160 GPa to 230 GPa.

The thickness of the protective member 7 is preferably 30 to 300 μm, and more preferably, 30 to 100 μm. When the thickness of the protective member 7 is less than 30 μm, the protective member 7 itself may be broken by the pressure in the firing step to be described below. Moreover, sufficient reinforcing effect of the superconducting connecting section C by the protective member 7 cannot be achieved. Consequently, the superconducting connecting section C may not be sufficiently protected from external loads. On the other hand, if the thickness of the protective member 7 exceeds 300 μm, stress is not applied to the connecting section and connection is not sufficient. Consequently, a critical current value Ic may decrease significantly. Therefore, by setting the thickness of the protective member 7 to be in a range from 30 μm to 300 μm, it is possible to suppress a decrease in the critical current value Ic that is a limit current value of the current flowing through the superconductor layer 3, while reinforcing the superconducting connecting section C. Note that the critical current value Ic can be obtained by measuring a connection resistance of the superconducting connecting section C by a four-terminal method, for example.

The width of the protective member 7 varies according to the width of the superconducting wires 10a and 10b. The width of the protective member 7 may be larger than the width of the superconducting wires 10a and 10b, and is not particularly limited. The width of the protective member 7 is preferably wider by 2 to 10 mm than the width of the superconducting wires 10a and 10b, and more preferably wider by 2 to 5 mm than the width of the superconducting wires 10a and 10b.

### (Metal Part)

The metal parts 9 are provided to opposing inner surfaces of the two protective members 7 and 7, respectively, and join the two protective members 7 and 7 to each other. It is preferable that the metal parts 9 are formed on the inner surfaces of the two protective members 7 and 7 at positions where the superconducting connecting section C is not located, for example. Further, when the superconducting wires 10a and 10b are pressurized and fired via the connecting superconductor layer 8 to form the superconducting connecting section C, it is preferable that the protective member 7 is made of a material capable of withstanding the firing temperature of about 800° C. Meanwhile, it is preferable that the metal part 9 is made of a material to be fused. Therefore, it is preferable that the material of the metal part 9 is different from that of the protective member 7. The metal part 9 may be made of metal that the metal parts 9 and 9 provided on the inner surfaces of the two protective members 7 and 7 respectively can be joined, and is not limited particularly. It is preferable that the metal part 9 is made of metal or alloy including at least one of Ag, Au, and Cu, and Ag is more preferable. The thickness of the metal part 9 is preferably 10 nm to 10 μm, and more preferably 10 nm to 2 μm. Formation of the metal part 9 is not particularly limited. For example, any publicly known method that enables formation of the metal part 9, such as sputtering, vacuum deposition, pasting, or the like, may be used.

### (Method of Manufacturing Connection Structure)

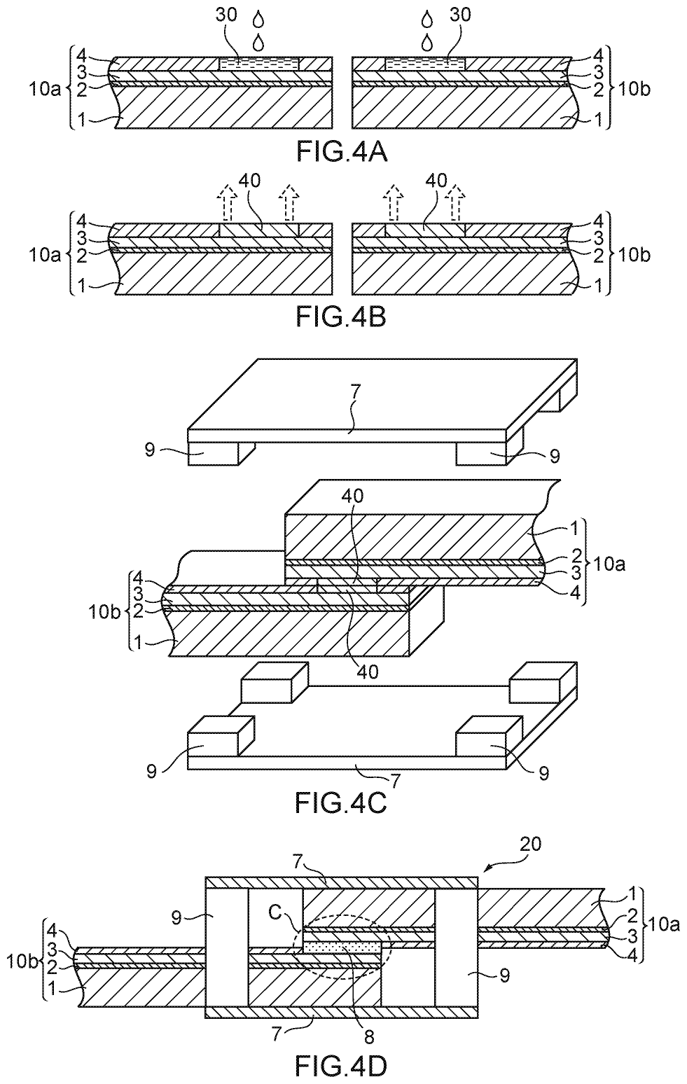

Next, a method of manufacturing a connection structure according to the present disclosure will be described with reference to FIGS. 4A to 4 D. FIG. 4A is a schematic cross-sectional view illustrating a step of applying a raw material for forming the connecting superconductor layer 8 on the superconducting wires 10a and 10b. FIG. 4B is a schematic cross-section view illustrating a pre-calcination step of the superconducting wires 10a and 10b on which the raw material is applied. FIG. 4C is a schematic cross-sectional perspective view illustrating a step immediately before forming a connection structure with use of the superconducting wires 10a and 10b and the two protective members 7. FIG. 4D is a schematic cross-sectional view of the connection structure 20 manufactured through the steps of FIGS. 4A to 4C. First, in the case where the superconducting wires 10a and 10b are coated with the metal protective layer 4, the metal protective layer 4 on the connecting end portion side is removed in a rectangular shape across the entire width of the superconducting wires 10a and 10b. Removal of the metal protective layer 4 in a rectangular shape is performed by mechanical polishing, chemical polishing (for example, etching process) or a combination of these processes (removing step). Note that removal of the metal protective layer 4 in a rectangular shape is performed up to a depth where the superconductor layer 3 is completely exposed. It is preferable that the surface roughness of the exposed superconductor layer 3 is sufficiently small. For example, the surface roughness (centerline average roughness Ra) of the superconductor layer 3 is preferably 50 nm or less, and more preferably 10 nm or less. Note that the surface roughness is an arithmetic average roughness Ra in an “amplitude average parameter in the height direction” of the surface roughness parameter defined in JIS B 0601:2001.

Then, as illustrated in FIG. 4A, the removed portion of the metal protective layer 4 of the superconducting wire 10a and 10b is filled with MOD solution 30 by spin coating or application by the metal organic deposition (MOD) method (application process). It is preferable that the MOD solution is a composition (solution) containing a metal composed of the same composition base as that of the superconductor layer 3.

The composition base that is the same as that of the superconductor layer 3 means that in the case where a RE-based superconductor is used as a high-temperature superconductor constituting the superconductor layer 3, a composition (solution) for forming the connecting superconductor layers 8 is also composed of a composition (solution) that is required for forming the RE-based superconductor. That is, a raw material required for forming a RE-based superconductor is included in the composition (solution), and both the superconductor layer 3 and the connecting superconductor layer 8 are configured of a superconducting composition of the same RE-based superconductor. The solvent contained in the composition (solution) is not limited particularly, as long as it can dissolve a desired superconducting base and the connecting superconductor layer 8 having good crystallinity can be obtained after the main calcination step. For example, an acetylacetonate-based or naphthenate-based MOD solution containing RE (rare earth element such as yttrium (Y), gadolinium (Gd), samarium (Sm), holmium (Ho), or the like), Ba, and Cu in a ratio of about 1:2:3 may be used.

Next, as illustrated in FIG. 4B, a pre-calcination step for removing organic components contained in the applied MOD solution is performed. In the pre-calcination step, the connecting end portions of the superconducting wires 10a and 10b are heat-treated in an atmosphere of N₂+O₂ gas within a temperature range of 400° C. to 500° C., and more preferably at 500° C. Thereby, on the rectangular removed portion on the connecting end side of the superconductor layer 3 of each of the superconducting wires 10a and 10b, a deposition layer 40 corresponding to the connecting superconductor layer 8 is formed.

Thereafter, as illustrated in FIG. 4C, the superconducting wire 10a is turned over and the deposition layers 40 and 40 of the superconducting wires 10a and 10b are opposed to each other and the deposition layers 40 and 40 are aligned and in close contact with each other to thereby form a layered structure. Furthermore, the two protective members 7 in each of which the metal part 9 has been joined to a desired position are prepared, and the layered structure is interposed between the two protective members 7 and 7. Then, the connecting end portions including the deposition layers 40 of the superconducting wires 10a and 10b are pressurized in the thickness direction via the protective members 7 and heated, whereby the main calcination step in the MOD method is performed. In the main calcination step, it is preferable that the connecting end portions of the superconducting wires 10a and 10b are heat-treated in an atmosphere of Ar+O₂ gas within a temperature range from 760° C. to 800° C. Thereby, the deposition layer 40 of the superconducting wire 10a and the deposition layer 40 of the superconducting wire 10b realize epitaxial growth (crystallization) while being in close contact with each other, and the integral connecting superconductor layer 8 is formed. Furthermore, the metal parts 9 and 9 respectively provided to opposing positions of the protective members 7 and 7 are integrated, and the two protective members 7 and 7 are fixed in a state of being applied with an attractive force in a direction of sandwiching the superconducting wires 10a and 10b.

Further, after the main calcination step, an oxygen annealing step of doping oxygen with respect to the connecting superconductor layer 8 is performed. In the oxygen annealing process, the connection end portions of the superconducting wires 10a and 10b are accommodated in an oxygen atmosphere, and are heated at a predetermined temperature. As a specific example, a portion subjected to oxygen annealing is placed under an oxygen atmosphere in a temperature range from 350° C. to 500° C. and oxygen doping is performed under this condition. Note that the connecting superconductor layer 8 is formed over the entire width of the superconducting wires 10a and 10b. Therefore, on both side faces in the width direction of the superconducting wires 10a and 10b, an end surface of the connecting superconductor layer 8 is in an exposed state, and oxygen doping can be performed effectively from the exposed end face. In this way, the connection structure 20 as illustrated in FIG. 4D is manufactured.

As described above, the connection structure obtained by the manufacturing method of the present disclosure has high connection strength, and the yield of the connection structure 20 can be improved.

### Second Embodiment

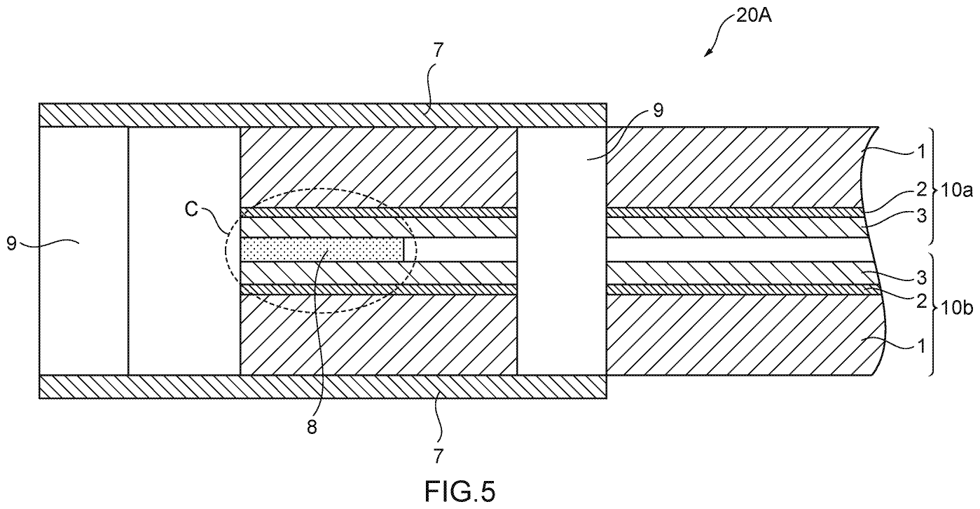

FIG. 5 is a schematic cross-sectional view of a connection structure of a second embodiment according to the present disclosure. A connection structure 20A illustrated in FIG. 5 has a connection structure in which two superconducting wires 10a and 10b are superposed and extend in the same direction. Even in such a connection structure in which the two superconducting wires 10a and 10b extend in the same direction, the superconducting wires 10a and 10b are connected with each other with high connection strength. As a result, in the superconducting connecting section C, occurrence of separation between the superconducting wires 10a and 10b can be suppressed, and the manufacturing yield of the connection structure 20A can be improved. It is also possible to effectively protect the superconducting connecting section C from the outside.

### Third Embodiment

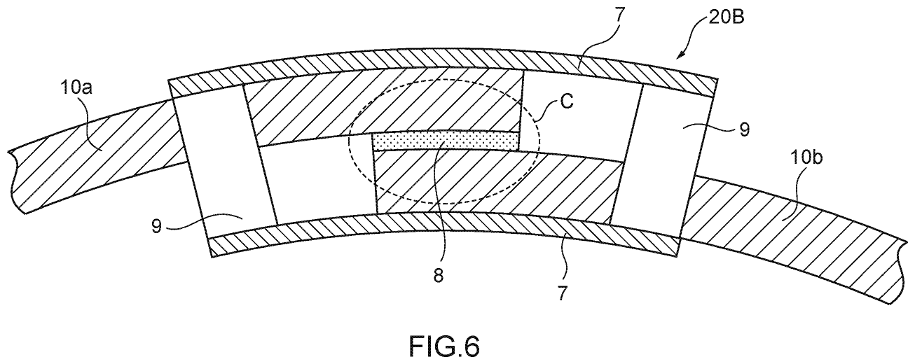

FIG. 6 is a schematic cross-sectional view of a connection structure 20B of a third embodiment according to the present disclosure. The connection structure 20B as illustrated has a structure in which end portions of the superconducting wires 10a and 10b are connected by the connecting superconductor layer 8 to form the superconducting connecting section C, two protective members 7 and 7 are disposed on the substrate (not illustrated) side of the superconducting wires 10a and 10b, and in particular, a curvature is provided so as to be applicable even in a coil. The degree of curvature varies depending on the flexural strength held by the components such as the superconducting wires 10a and 10b, the protective member 7, and the like. The degree of curvature can be designed appropriately to the extent not to affect the various members. Note that while the superconducting wires 10a and 10b illustrated in FIG. 6 are configured of the substrate 1, the intermediate layer 2, the superconductor layer 3, and the metal protective layer 4, details of the layered structure of these components are not illustrated. With the structure having a curvature as described above, in the superconducting connecting section C in a coil, occurrence of separation between the superconducting wires 10a and 10b can be suppressed, and the manufacturing yield of the connection structure 20B can be improved. It is also possible to effectively protect the superconducting connecting section C from the outside.

### Fourth Embodiment

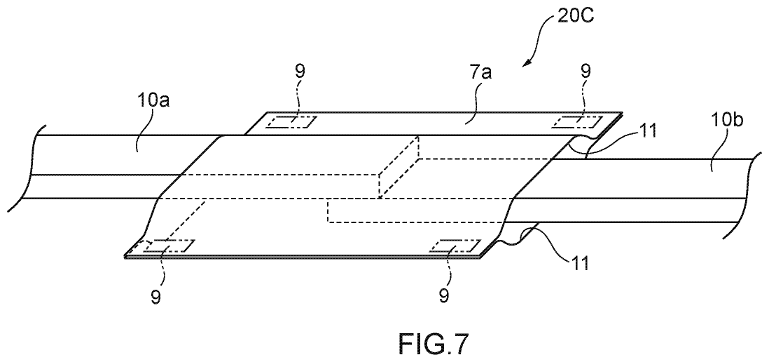

FIG. 7 is a perspective view of a connection structure 20C of a fourth embodiment according to the present disclosure. As illustrated in FIG. 7, in the fourth embodiment, a protective member 7a is not a flat plate but has a configuration having a stepped recessed portion 11 for accommodating end portions of the superconducting wires 10a and 10b by folding a plate to have a hat-shaped cross section such that it becomes wider than the width of the superconducting wires 10a and 10b extending in the longitudinal direction, in a central portion of a width direction. Then, the two protective members 7a are arranged such that the stepped recessed portions 11 and 11 face each other, and the superconducting connecting section C is interposed between the two stepped recessed portions 11 and 11 from up and down, and portions of the protective members 7a and 7a that are outside in the width direction of the stepped recessed portion 11 and at four corners surrounding the superconducting connecting section C are joined by the metal parts 9. Even with such a configuration, in the superconducting connecting section C, occurrence of separation between the superconducting wires 10a and 10b can be suppressed, and the manufacturing yield of the connection structure 20C can be improved. It is also possible to effectively protect the superconducting connecting section C from the outside.

### Fifth Embodiment

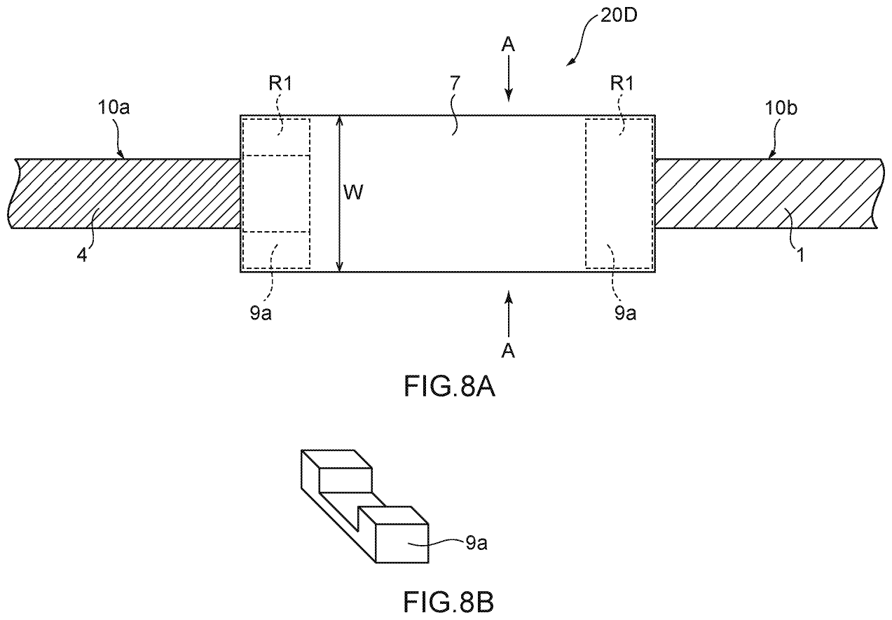

FIG. 8A is a top view of a connection structure 20D of a fifth embodiment according to the present disclosure. The connection structure 20D as illustrated shows the case where metal parts 9a are formed over the entire area in the width direction W at both end portions in the longitudinal direction of the protective member 7. In FIG. 8, parts of areas R1 (areas surrounded by broken lines in FIG. 8) indicate areas where the metal parts 9a are formed. Here, as illustrated in FIG. 8B, the metal part 9a has a cross section in an arch shape such that the metal part 9a does not contact the superconductor layer 3 or the metal protective layer 4 covering the superconductor layer 3, although it contacts the substrate 1. When manufacturing the connection structure 20D having such a configuration, by supplying oxygen from a direction of arrow A, it is possible to supply oxygen to the inside of the connection structure 20D through a gap G (not illustrated) existing between the two protective members 7 and 7. Further, in the fifth embodiment, since the metal part 9a is brought into contact with the substrate 1, there is an advantage that it can be fixed more firmly.

### Sixth Embodiment

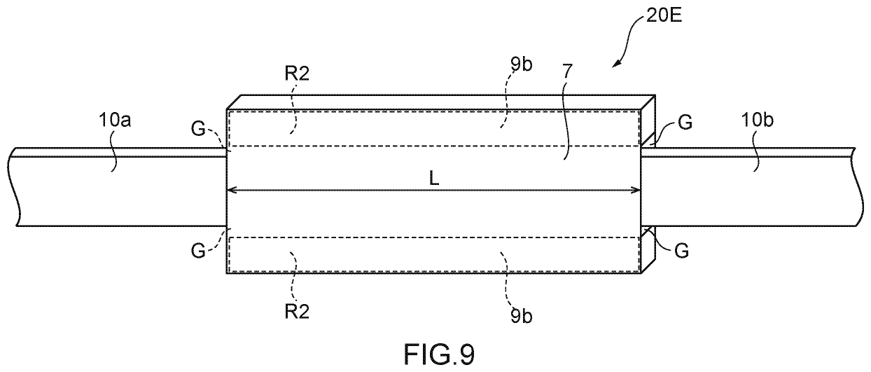

FIG. 9 is a perspective view of a connection structure 20E of a sixth embodiment according to the present disclosure. The connection structure 20E as illustrated shows the case where metal parts 9b are formed between the two protective members 7 and 7 over the entire area in the longitudinal direction L at both end portions in the width direction of the protective members 7 and 7. In FIG. 9, parts of areas R2 (areas surrounded by broken lines in FIG. 9) indicate areas where the metal parts 9b are formed. When manufacturing the connection structure 20E having such a configuration, oxygen can be supplied from gaps G between the metal parts 9b and the superconducting wires 10a and 10b.

### Seventh Embodiment

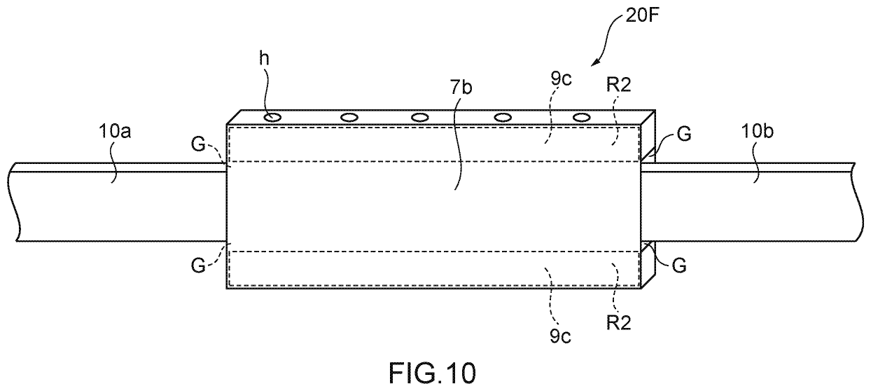

FIG. 10 is a perspective view of a connection structure 20F of a seventh embodiment according to the present disclosure. The point that the case where the metal parts 9c are formed over the entire area in the longitudinal direction at both end portions in the width direction of the protective member 7b is shown is similar to the case of the fifth embodiment. However, the point that the metal part 9c is further provided with an oxygen introduction hole h to introduce oxygen, from the outer surface of the metal part 9c through the inner surface, is different. Thereby, when manufacturing the connection structure, it is possible to further supply oxygen via the oxygen introduction hole h, not only via the gap G between the metal part 9c and the superconducting wires 10a and 10b.

While the connection structures according to the embodiments have been described above, the present disclosure is not limited to the embodiments described above. Various variants and changes can be made based on the technical concept of the present disclosure.

In the connection structure 20 according to the present disclosure, a space portion may be filled with resin such as epoxy resin in order to prevent oxidation of metal due to air contact.

What is claimed is:

1. A connection structure comprising:
first and second superconducting wires that are two superconducting wires each having a substrate in a tape shape, an intermediate layer formed on the substrate, and a superconductor layer formed on the intermediate layer;
a connecting superconductor layer that connects the first and second superconducting wires in a positional relationship in which surfaces of the superconductor layers face each other, and forms a superconducting connecting section together with the first and second superconducting wires;
two protective members each having a width larger than a width of the first and second superconducting wires, and disposed on substrate sides of the first and second superconducting wires in a positional relationship of sandwiching the superconducting connecting section; and
a metal part that joins the two protective members to each other.

2. The connection structure according to claim 1, wherein
each of the first and second superconducting wires further includes a metal protective layer that covers an entire surface of the superconductor layer except for the superconducting connecting section.

3. The connection structure according to claim 1, wherein
the metal parts are provided in at least four positions surrounding the superconducting connecting section.

4. The connection structure according to claim 1, wherein
the metal part is metal or alloy including at least one of Ag, Au, and Cu.

5. The connection structure according to claim 1, wherein
a difference between an elastic coefficient of the substrate and an elastic coefficient of the protective member is in a range of 80 GPa or less.

6. The connection structure according to claim 1, wherein
an elastic coefficient of the protective member ranges from 150 GPa to 250 GPa.

7. The connection structure according to claim 1, wherein
a melting point of the protective member is equal to or higher than 1000° C.

8. The connection structure according to claim 1, wherein
a thickness of the protective member ranges from 30 μm to 300 μm.

9. The connection structure according to claim 1, wherein
the protective member is Ni-based alloy, stainless steel, or carbon steel.
